(19) United States
(12) Patent Application Publication
(10) Pub. No.: US 2018/0212167 A1
(43) Pub. Date: Jul. 26, 2018

(54) FLEXIBLE DISPLAY PANEL, FLEXIBLE DISPLAY APPARATUS HAVING THE SAME, AND FABRICATING METHOD THEREOF

(71) Applicants: BOE TECHNOLOGY GROUP CO., LTD., Beijing (CN); Chengdu BOE Optoelectronics Technology Co., Ltd., Chengdu (CN)

(72) Inventors: Pil Geun Chun, Beijing (CN); Chuan Peng, Beijing (CN); Jinsan Park, Beijing (CN); Jinhwan Hwang, Beijing (CN)

(73) Assignees: BOE TECHNOLOGY GROUP CO., LTD., Beijing (CN); Chengdu BOE Optoelectronics Technology Co., Ltd., Chengdu (CN)

(21) Appl. No.: 15/544,636

(22) PCT Filed: Nov. 15, 2016
(86) PCT No.: PCT/CN2016/105827

§ 371 Date: Jul. 19, 2017

(30) Foreign Application Priority Data
Jul. 11, 2016 (CN) 201610543683.4

(51) Int. Cl. H01L 51/00; H01L 51/56; H01L 51/52; G02F 1/1333; G02F 1/1335; H01L 27/12; H01L 27/32; G06F 3/041; G06F 3/044

(52) U.S. Cl. CPC H01L 51/0097; H01L 51/56; H01L 51/524; G02F 1/133305; G02F 1/133512; G06F 3/044; G02F 1/13338; H01L 27/124; H01L 27/3276; H01L 27/323; G06F 3/0412; G02F 1/133514

(57) ABSTRACT

The present application discloses a flexible display panel having a display substrate and an encapsulation substrate facing the display substrate. The encapsulation substrate includes a first base substrate. The display substrate includes a second base substrate; a display unit on the second base substrate; and an encapsulating layer on a side of the display unit distal to the second base, substrate and proximal to the encapsulation substrate. The second base substrate includes a moisture-resistant and oxygen-resistant inorganic material having an etching rate smaller than that of a glass substrate for an etchant for etching the glass substrate.

### CROSS-REFERENCE TO RELATED APPLICATION

This application claims priority to Chinese Patent Application No. 201610543683.4, filed Jul. 11, 2016, the contents of which are incorporated by reference in the entirety.

### TECHNICAL FIELD

The present invention relates to a flexible display panel, a flexible display apparatus having the same, and a fabricating method thereof.

### BACKGROUND

In conventional, flexible display panels, the base substrate is made of a polymer material such as polyimide. Sometimes, the base substrate in the conventional flexible display panels further includes a barrier sub-layer made of an inorganic material. The barrier layer is formed by depositing an inorganic material on the polymer base substrate. In a thin film encapsulation process, the conventional flexible display panel is encapsulated by multiple sub-layers include an organic sub-layer and an inorganic sub-layer. The polymer base substrate is flexible, resulting in a flexible or foldable display panel.

### SUMMARY

In one aspect, the present invention provides a flexible display panel comprising a display substrate and an encapsulation substrate facing the display substrate; wherein the encapsulation substrate comprises a first base substrate; the display substrate comprises a second base substrate; a display unit on the second base substrate; and an encapsulating layer on a side of the display unit distal to the second base substrate and proximal to the encapsulation substrate; and the second base substrate comprises a moisture-resistant and oxygen-resistant inorganic material having an etching rate smaller than that of a glass substrate for an etchant for etching the glass substrate.

Optionally, the encapsulating layer comprises an inorganic material having, a high hermeticity and has a thickness in a range of approximately 0.01 μm to approximately 10 μm.

Optionally, the first base substrate has a thickness no more than approximately 0.1 mm.

Optionally, the second base substrate has an etching rate smaller than that of the first base substrate for an etchant for etching the first base substrate.

Optionally, the first base substrate is a strengthened glass substrate.

Optionally, the flexible display panel further comprises a touch sensor on a side of the first base substrate proximal to the encapsulating layer.

Optionally, the second base substrate comprises one or more of a silicon-containing inorganic material and a metal material.

Optionally, the second base substrate comprises one or more of silicon nitride (SiNₓ), amorphous silicon, polycrystalline silicon, gold, platinum, copper, molybdenum, and nickel.

Optionally, the second base substrate comprises a sub-layer on a surface distal to the encapsulation substrate, the sub-layer being substantially resistant to the etchant for etching the glass substrate.

Optionally, the encapsulating layer comprises one or more of silicon nitride (SiNₓ) and silicon oxynitride (SiNₓO_{y}).

Optionally, the flexible display panel is a flexible organic light emitting diode display panel, and the display unit comprises an organic light emitting diode.

In another aspect, the present invention provides a method of fabricating a flexible display panel, comprising forming a encapsulation substrate comprising a first base substrate; forming a display substrate facing the encapsulation substrate on a third base substrate, the third base substrate having a thickness smaller than that of the first base substrate; adhering the display substrate to the encapsulation substrate; and etching the first base substrate and the third base substrate in a same process to reduce a thickness of the first base substrate and remove the third base substrate thereby exposing the display substrate.

Optionally, the step of forming the display substrate comprises forming a second base substrate on the third base substrate; forming a display unit on a side of the second base substrate distal to the third base substrate; and forming an encapsulating layer to encapsulate the display unit, the encapsulating layer being formed on a side of the display unit distal to the second base substrate and proximal to the encapsulation substrate; the method further comprising adhering the encapsulation substrate to the display substrate thereby sealing the display unit therebetween; and etching the first base substrate and the third base substrate in a same process to reduce a thickness of the first base substrate and remove the third base substrate thereby exposing the second base substrate; wherein the second base substrate comprises a moisture-resistant and oxygen-resistant inorganic material having an etching rate smaller than that of the third base substrate for an etchant for etching the third base substrate.

Optionally, the method further comprises strengthening the first base substrate subsequent to etching the first base substrate and the third base substrate in the same process thereby forming a strengthened first base substrate.

Optionally, prior to etching the first base substrate and the third base substrate in a same process, the first base substrate has a thickness in a range of approximately 0.2 mm to approximately 1.0 mm; and a difference between the thickness of the third base substrate and that of the first base substrate is no more than 0.1 mm.

Optionally, a thickness of the first base substrate is reduced to a thickness of no more than approximately 0.1 mm subsequent to etching the first base substrate and the third base substrate in the same process.

Optionally, forming the second base substrate comprises forming a sub-layer on a surface proximal to the third base substrate, the sub-layer being substantially resistant to the etchant for etching the glass substrate.

Optionally, the encapsulating layer is formed using an inorganic material having a high hermeticity, and is formed to have a thickness in a range of approximately 0.01 μm to approximately 1.0 μm.

In another aspect, the present invention provides a flexible display panel fabricated by a method described herein.

In another aspect, the present invention provides a flexible display apparatus comprising a flexible display panel described herein or fabricated by a method described herein.

### BRIEF DESCRIPTION OF THE FIGURES

The following drawings are merely examples for illustrative purposes according to various disclosed embodiments and are not intended to limit the scope of the present invention.

FIG. 1 is a diagram illustrating the structure of a flexible display panel in some embodiments according to the present disclosure.

FIG. 2 is a diagram illustrating the structure of a flexible display panel in some embodiments according to the present disclosure.

FIG. 3 is a diagram illustrating the structure of a flexible display panel in some embodiments according to the present disclosure.

FIG. 4A is a diagram illustrating the structure of a touch sensor in a flexible display panel in some embodiments according to the present disclosure.

FIG. 4B is a diagram illustrating the structure of a touch sensor in a flexible display panel in some embodiments according to the present disclosure.

FIG. 5 is a diagram illustrating the structure of a touch sensor in a flexible display panel in some embodiments according to the present disclosure.

FIG. 6A is a diagram illustrating the structure of a touch sensor in a flexible display panel in some embodiments according to the present disclosure.

FIG. 6B is a diagram illustrating the structure of a touch sensor in a flexible display panel in some embodiments according to the present disclosure.

FIG. 7 is a flow chart illustrating a process of fabricating a. flexible display panel in sonic embodiments according to the present disclosure.

FIGS. 8A-8C shows a process of fabricating a flexible display panel in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

In conventional flexible display panels having a polymer base substrate, fabrication defects such as bubble and orifice in the polymer base substrate, as well as heat ductility of the base substrate, affect product quality of the flexible display panel. For example, the existence of the fabrication detects in the polymer base substrate leads to defects at the same location in the inorganic barrier layer attached to the polymer base substrate. These defects render a base substrate moisture permeable and oxygen permeable, resulting in an inferior product. Moreover, the conventional flexible display panel having a polymer base substrate is prone to scratches and damages.

Accordingly, the present invention provides, inter alia, a flexible display panel, a flexible display apparatus having the same, and a fabricating method thereof that substantially obviate one or more of the problems due to limitations and disadvantages of the related art. In one aspect, the present disclosure provides a flexible display panel having a encapsulation substrate and a display substrate facing the encapsulation substrate. In some embodiments, the encapsulation substrate includes a first inorganic base substrate; the display substrate includes a second inorganic base substrate; a display unit on the second inorganic base substrate; and an encapsulating layer one side of the display unit distal to the second inorganic base substrate and proximal to the encapsulation substrate; and the second inorganic base substrate includes a moisture-resistant and oxygen-resistant inorganic material having an etching rate smaller than that of a glass substrate for an etchant for etching the glass substrate. Optionally, the first inorganic base substrate is a cover glass for the flexible display panel. Optionally, the first inorganic base substrate is a strengthened inorganic base substrate.

As used herein, the term “display unit” refers to a combination of a first portion of the display panel for displaying an image and a second portion which is a driving unit for displaying the image. Optionally, the present display panel is an organic light emitting diode display panel. Optionally, the display panel is an organic light emitting diode display panel, and the display unit in the organic light emitting diode display panel refers to an organic light-emitting diode and a thin film transistor for driving the same. Optionally, the present display panel is a liquid crystal display panel. Optionally, the present display panel is a liquid crystal display panel, and the display unit in the liquid crystal display panel refers to a liquid crystal layer, a common electrode, a pixel electrode, as well as a thin film transistor for driving image display.

As used herein, the term “strengthened” or “strengthening” in the context of the present disclosure refers to a base substrate that has been strengthened by various appropriate methods. Optionally, the base substrate is chemically strengthened, e.g., through ion-exchange of larger ions for smaller ions in the surface of the base substrate (e.g., a glass substrate). Optionally, the base substrate is thermally strengthened, i.e., tempered. Optionally, a strengthened base substrate has a surface compressive stress in its surface that aids in the strength preservation of the base substrate. Optionally, a strengthened base substrate refers to a chemically strengthened base substrate.

FIG. 1 is a diagram illustrating the structure of a flexible display panel in some embodiments according to the present disclosure. Referring to FIG. 1, the flexible display panel in some embodiments includes an encapsulation substrate 20 and a display substrate 10 facing the encapsulation substrate 20. The encapsulation substrate 20 may be a counter substrate in some embodiments having a first inorganic base substrate. The display substrate 10 may be an array substrate in some embodiments having a second inorganic base substrate 11. As shown in FIG. 1, the display substrate 10 includes a second inorganic base substrate 11; a display unit 12 on the second inorganic base substrate 11; and an encapsulating layer 13 on a side of the display unit 12 distal to the second inorganic base substrate 11 and proximal to the encapsulation substrate 20.

Optionally, the first inorganic base substrate, is a strengthened glass substrate.

Optionally, the second inorganic base substrate 11 includes a moisture-resistant and oxygen-resistant inorganic material having an etching rate smaller than that of a glass substrate for an etchant for etching the glass substrate. Optionally, the second inorganic base substrate has an etching rate smaller than that of the first inorganic base substrate for an etchant for etching the first inorganic base substrate.

Various appropriate materials and various appropriate fabricating methods may be used to make the second inorganic base substrate. For example, an inorganic base substrate material may be deposited by a plasma-enhanced chemical vapor deposition (PECVD) process. Examples of appropriate materials for making the second inorganic base substrate include, but are not limited to, a silicon-containing inorganic material and a metal material. Examples of silicon-containing inorganic materials include silicon nitride (SiNₓ), amorphous silicon, and polycrystalline silicon. Examples of metal materials include gold, platinum, copper, molybdenum, and nickel.

Optionally, the second inorganic base substrate has a single-layer structure. Optionally, the second inorganic base substrate has a stacked-layer structure including two or more sub-layers. Optionally, the stacked-layer structure includes a metal sub-layer and a sub-layer made of a silicon-containing inorganic material.

In some embodiments, fabrication of the flexible display panel involves forming the second inorganic base substrate on a third inorganic base substrate (i.e., a carrier substrate), and assembling the encapsulation substrate to the display substrate together, and etching the first inorganic base substrate and the third inorganic base substrate in a same process, during which the third inorganic base substrate is removed. Accordingly, for making the second inorganic base substrate, an inorganic material having an etching rate smaller than that of the third inorganic base substrate for an etchant for etching the thud inorganic base substrate is selected. For example, an inorganic material having an etching rate no more than 0.2 μm/minute may be selected for making the second inorganic base substrate.

Optionally, the first inorganic base substrate is made of substantially the same material as the third inorganic base substrate. The first inorganic base substrate has an etching rate substantially the same as the third inorganic base substrate for an etchant for etching the third inorganic base substrate.

In some embodiments, the third inorganic base substrate is a glass substrate. Various appropriate etchants may be used for etching the glass substrate, including hydrofluoric acid, nitric acid, or a combination thereof, arid optionally with one or more additives. Optionally, the second inorganic base substrate has an etching rate smaller than that of the third inorganic base substrate for an etchant including hydrofluoric acid. Optionally, the second inorganic base substrate has an etching rate of no more than 0.2 μm/minute for an etchant including hydrofluoric acid.

In some embodiments, a metal material having an etching rate smaller than that of the third inorganic base substrate for an etchant for etching the third inorganic base substrate is selected as the material for making the second inorganic base substrate. A large number of metals are resistant to the etchant for etching a glass substrate. For example, many insert metals are resistant to the glass etchant.

In some embodiments, the second inorganic base substrate includes a sub-layer on a surface distal to the encapsulation substrate (e.g., proximal to the third inorganic base substrate). The sub-layer is substantially resistant to the etchant for etching the glass substrate. For example, when the second inorganic base substrate is made of a metal material or includes a metal sub-layer, it may include a passivating protective sub-layer (e.g., an oxide protective film) on a surface proximal to the third inorganic base substrate.

The second inorganic base substrate may have various appropriate thickness sufficient for providing requisite moisture resistance and oxygen resistance in the flexible display panel. Depending on the design needs, an appropriate thickness of the second inorganic base substrate may be selected for making a specific type of display panel, e.g., an ultrathin display panel, a foldable display panel, a rollable display panel, as well as flexible display panels having various curvatures.

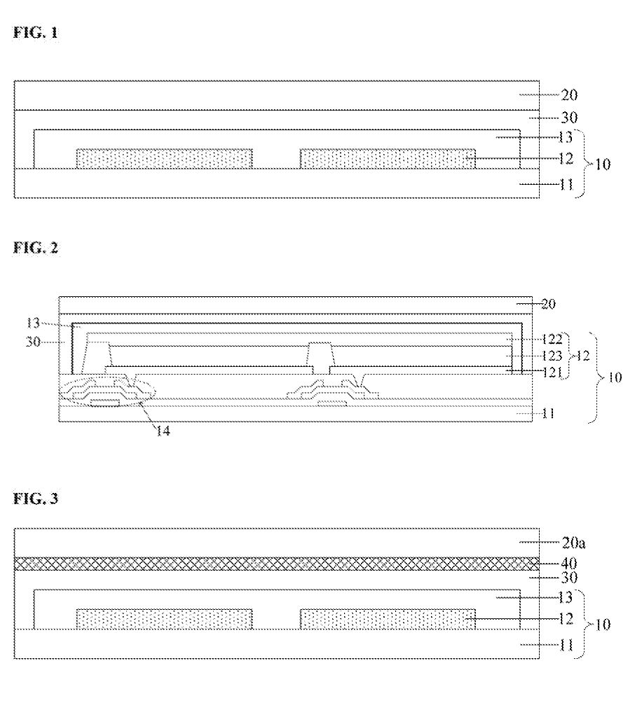

FIG. 2 is a diagram illustrating the structure of a flexible display panel in some embodiments according to the present disclosure. Referring to FIG. 2, the flexible display panel in some embodiments is a flexible organic light emitting diode display panel, and the display unit includes an organic light emitting diode 12. The flexible display panel includes a plurality of subpixels, each of which has a display unit. Optionally, the organic light emitting diode 12 includes an anode 121, an organic functional layer 123 on the anode 121, and a cathode 122 on a side of the light emitting layer 123 distal to the anode 121. The organic functional layer 123 may include a hole transport layer on the anode, a light emitting layer on a side of the hole transport layer distal to the anode, an electron transport layer on a side of the light emitting layer distal to the hole transport layer. Optionally, for enhancing light emitting efficiency, the organic functional layer 123 further includes a hole injection layer on a side of the hole transport layer proximal to the anode 121, and an electron injection layer on a side of the electron transport layer proximal to the cathode 122.

Referring to FIG. 2, the display substrate 10 further includes a plurality of thin film transistors 14. The thin film transistor 14 includes an active layer, a gate electrode, a gate insulating layer between the active layer and the gate insulating layer, a source electrode and a drain electrode. The drain electrode is electrically connected to the anode 121. Various appropriate semiconductor materials may be used for making the thin film transistor, including amorphous silicon, polycrystalline silicon, various metal oxides, various organic semiconductors. Optionally, the thin film transistor is a top gate-type thin film transistor. Optionally, the thin film transistor is a bottom gate-type thin film transistor

The encapsulating, layer may be made of any appropriate material (e.g., an inorganic material) and have various appropriate thickness, sufficient for providing requisite moisture resistance and oxygen resistance in the flexible display panel (e.g., in combination with the first inorganic base substrate).

The first inorganic base substrate may have various appropriate thickness sufficient for providing requisite moisture resistance and oxygen resistance in the flexible display panel. Depending on the design needs, an appropriate thickness of the first inorganic base substrate may be selected for making a specific type of display panel, e.g., an ultrathin display panel, a foldable display panel, a rollable display panel, as well as flexible display panels having various curvatures.

In the present flexible display panel, the first base substrate and the second base substrate are made of an inorganic material having a high hermeticity, rendering the flexible display panel product highly resistant to moisture and oxygen. In contrast, the conventional flexible display panel uses polymer materials for making base substrates. Fabrication defects often render the polymer base substrates moisture permeable and oxygen permeable. Even in display panels having an inorganic barrier sub-layer in addition to the polymer base substrates, it is still difficult to achieve satisfactory moisture resistance and oxygen resistance in the conventional flexible display panel.

In some embodiments, the present flexible display panel further includes an optical adhesive layer for adhering the encapsulation substrate to the display substrate thereby sealing the display unit therebetween. Optionally, the optical adhesive layer is made of an optical clear resin. Referring to FIG. 1 and FIG. 2, the flexible display panel in some embodiments includes an optional clear resin layer 30 between the encapsulation substrate 20 and the display substrate 10, further encapsulating the display unit 12 in the flexible display panel.

The present flexible display panel has several advantages over the conventional flexible display panels. First, the base substrate of the display substrate is made of an inorganic material, and is fabricated by directly depositing an inorganic material on a carrier substrate. The second base substrate in the present flexible display panel has excellent surface planarity, surface smoothness, mechanical stability, and structural integrity. Second, the base substrates in the present flexible display panel are made of inorganic materials having a high hermeticity, obviating the fabrication defects in the conventional flexible display panel having a polymer base substrate. Third, the display unit in the present flexible display panel is encapsulated multiple times, e.g., by the encapsulating layer and the first inorganic base substrate having a high hermeticity, resulting in a flexible display panel highly resistant to moisture and oxygen. Fourth, the base substrates are made of inorganic material such as a strengthened glass material having a high hardness and scratch resistance, obviating the need of having an additional cover glass, resulting in an ultrathin flexible display panel having a simplified structure.

Optionally, the encapsulating layer has a thickness in the range of approximately 0.01 μm to approximately 10 μm, e.g., approximately 0.01 μm to approximately 1.0 μm, approximately 1.0 μm to approximately 1.5 μm, approximately 1.5 μm to approximately 2.0 μm, approximately 2.0 μm to approximately 5.0 μm, approximately 5.0 μm to approximately 10 μm. Optionally, the encapsulating layer has a thickness of approximately 0.1 μm. Optionally, the encapsulating layer has a thickness of approximately 1.0 μm. Optionally, the encapsulating layer has a thickness of approximately 1.5 μm, Optionally, the encapsulating layer has a thickness of approximately 2.0 μm. Optionally, the encapsulating layer has a thickness of approximately 5.0 μm.

Optionally, the encapsulating layer is made of an inorganic material having a high hermeticity. Examples of appropriate inorganic materials for making the encapsulating layer include, but are not limited to, silicon nitride (SiNₓ) and silicon oxynitride (SiNₓO_{y}). Silicon nitride materials are highly hydrophobic and highly hermetic. Silicon oxynitride materials have excellent bonding with other layers of the flexible display panel. Moreover, an encapsulating layer made of one or more of these material have excellent surface planarity. A flexible display panel having an encapsulating layer made of one or more of these materials is highly resistant to external moisture and oxygen.

In the present flexible display panel, the display unit is encapsulated multiple times, e.g., by the encapsulating layer and the first inorganic base substrate having a high hermeticity, completely eliminating any permeation pathway for external moisture and oxygen. As a result, it is not requisite to have an encapsulating layer having multiple organic and inorganic sub-layers. A simplified and cost-effective fabrication process is made possible.

Optionally, the first inorganic base substrate has a thickness no more than approximately 0.1 mm, e.g., in a range of approximately 0.05 mm to approximately 0.1 mm. By having this design, the flexible display panel may be made ultrathin, flexible, foldable, and rollable.

Optionally, the first inorganic base substrate has a thickness larger than 0.1 mm.

Optionally, the first inorganic base substrate has a Moh's hardness in a range of approximately 8 to approximately 9.

In some embodiments, the flexible display panel further includes a touch sensor. Optionally, the touch sensor is in the encapsulation substrate. Optionally, the touch sensor is in the display substrate.

FIG. 3 is a diagram illustrating the structure of a flexible display panel in some embodiments according to the present disclosure. Referring to FIG. 3, the flexible display panel in some embodiments includes a touch sensor 40 on a side of the first inorganic base substrate 20a proximal to the encapsulating layer 13.

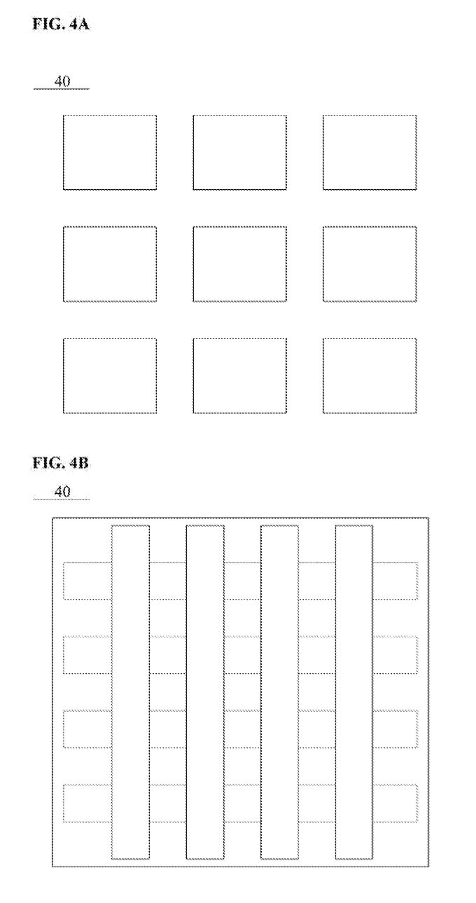

FIG. 4A is a diagram illustrating the structure of a touch sensor in a flexible display panel in some embodiments according to the present disclosure. Referring to FIG. 4A, the touch sensor 40 is a self-capacitive touch sensor having a touch electrode layer.

FIG. 4B is a diagram illustrating the structure of a touch sensor in a flexible display panel in some embodiments according to the present disclosure. Referring to FIG. 4B, the touch sensor 40 is a mutual capacitive touch sensor having a touch sensing electrode layer and a touch scanning electrode layer. The touch sensing electrode layer and the touch scanning electrode layer are insulated from each other by an insulating layer.

Various appropriate electrode materials and various appropriate fabricating methods may be used for making the touch sensor. For example, the electrode materials may be deposited by a plasma-enhanced chemical vapor deposition (PECVD) process or fabricated by a nanoimprinting lithography process. Examples of appropriate electrode materials for making the touch sensor include, but are not limited to, indium tin oxide, nano-silver, metal mesh, graphene, and carbon nanotubes.

To the present flexible display panel, the touch sensor is disposed on a side of the first inorganic base substrate proximal to the encapsulating layer, thereby integrating the touch control function in the display module. This design obviates the need of adhering an add-on touch panel to the display module, significantly reducing the overall thickness of the flexible display panel. The resulting flexible display panel may be made thinner and more flexible.

In some embodiments, the flexible display panel Rather includes a color filter. Optionally, the color filter is in the encapsulation substrate. Optionally, the color filter is in the display substrate. FIG. 5 is a diagram illustrating the structure of a touch sensor in a flexible display panel in some embodiments according to the present disclosure. Referring to FIG. 5, the flexible display panel in some embodiments further includes a color filter 50 on a side of the first inorganic base substrate 20a proximal to the encapsulating layer 13. Optionally, as shown in. FIG. 5, the display substrate 10 includes a plurality of pixels, each of which comprising a subpixel of a first color 101, a subpixel of a second color 102, and a subpixel of a third color 103. The color filter 50 includes a first color filter layer 501 corresponding to the subpixel of the first color 101, a second color filter layer 502 corresponding to the subpixel of the second color 102, and a third color filter layer 503 corresponding to the subpixel of the third color 103. Optionally, the first color, the second color, and the third color are three different colors selected from red, green, and blue. Optionally, the subpixel of a first color 101, the subpixel of a second color 102, and the subpixel of a third color 103 are three subpixels selected from a red subpixel, a green subpixel, and a blue subpixel. Optionally, the first color filter layer 501, the second color filter layer 502, and the third color filter layer 503 are three color filter layers selected from a red color filter layer, a green color filter layer, and a blue color filter layer.

By having a color filter in the flexible display panel, e.g., on a side of the first inorganic base substrate proximal to the encapsulating layer, ambient light reflected by thin film transistor and display unite ay be reduced or eliminated, enhancing display contrast. The color filter may be made to have a thickness much smaller than a polarizer. For example, the color filter in some embodiments may be made by a resin material having a thickness in a range of approximately 2 μm to approximately 6 μm. As compared to conventional flexible display panel, the present flexible display panel may be made thinner and more flexible.

In some embodiments, the flexible display panel further includes a black matrix layer, e.g., on a side of the first inorganic base substrate proximal to the encapsulating layer. The black matrix layer is disposed in an inter-subpixel region of the flexible display panel, preventing color mixing at adjacent subpixels. As used herein, an inter-subpixel region refers to a region between adjacent subpixel regions, such as a region corresponding to a black matrix in a liquid crystal display panel, a region corresponding a pixel definition layer in an organic light emitting diode display panel, or a black matrix in the present display panel. Optionally, the inter-subpixel region is a region between adjacent subpixel regions in a same pixel. Optionally, the inter-subpixel region is, a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

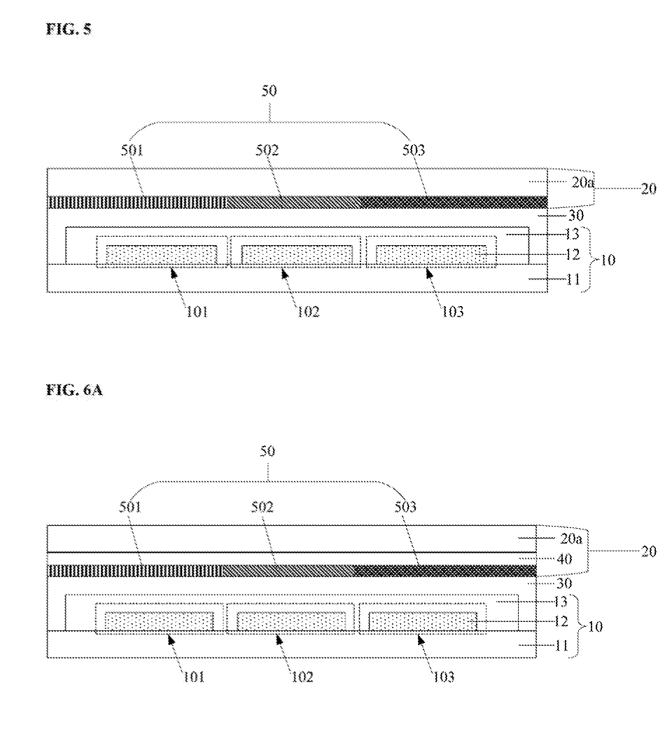

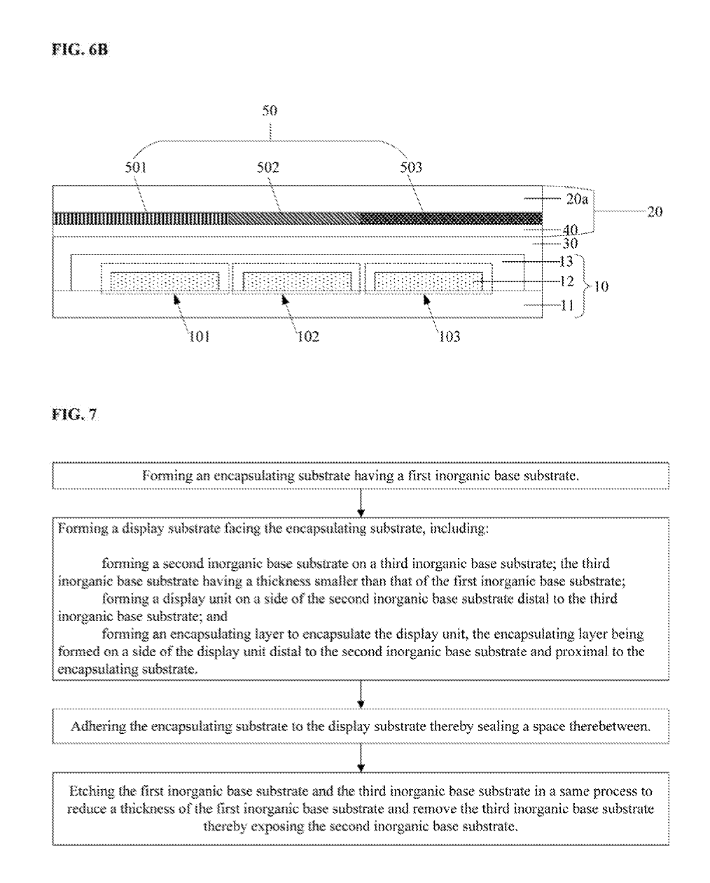

FIG. 6A is a diagram illustrating the structure of a touch sensor in a flexible display panel in some embodiments according to the present disclosure. Referring to FIG. 6A, the encapsulation substrate 20 includes a first inorganic base substrate 20a, a touch sensor 40 on the first inorganic base substrate 20a, and a color filter 50 on a side of the touch sensor 40 distal to the first inorganic base substrate 20a and proximal to the encapsulating layer 13 in the display substrate 10. The color filter 50 includes a first color filter layer 501, a second color filter layer 502, and a third color filter layer 503. By having this design, the touch sensor 40 is directly disposed on the first inorganic base substrate 20a. Because the first inorganic base substrate 20a is substantially planar, the touch sensor 40 can be made substantially planar, preventing occurrence of manufacturing defects. Optionally, the touch sensor 40 in some embodiments is made of one or more materials selected from graphene and carbon nanotubes.

FIG. 6B is a diagram illustrating the structure of a touch sensor in a flexible display panel in some embodiments according to the present disclosure. Referring to FIG. 6B, the encapsulation substrate 20 includes a first inorganic base substrate 20a, a color filter 50 on the first inorganic base substrate 20a, and a touch sensor 40 on a side of the color filter 50 distal to the first inorganic base substrate 20a and proximal to the encapsulating layer 13 in the display substrate 10. The color filter 50 includes a first color filter layer 501, a second color filter layer 502, and a third color filter layer 503. By having this design, the color filter not only eliminates light reflected by the display unit 12 and the thin film transistor, but also light reflected by the touch sensor 40, further enhancing display quality. Optionally, the touch sensor 40 in some embodiments is made of one or more materials selected from indium tin oxide, nano-silver, metal mesh, grapheme, and carbon nanotubes.

In another aspect, the present disclosure provides a method of fabricating a flexible display panel. FIG. 7 is a flow chart illustrating a process of fabricating a flexible display panel in some embodiments according to the present disclosure. Referring to FIG. 7, the method in some embodiments includes forming an encapsulation substrate having a first inorganic base substrate and forming a display substrate facing the encapsulation substrate. The step of forming the display substrate includes forming a second inorganic base substrate on a third inorganic base substrate; the third inorganic base substrate haying a thickness smaller than that of the first inorganic base substrate, forming a display unit on a side of the second inorganic base substrate distal to the third inorganic base substrate; and forming an encapsulating layer to encapsulate the display unit, the encapsulating layer being formed on a side of the display unit distal to the second inorganic base substrate and proximal to the encapsulation substrate. The method in sonic embodiments further includes adhering the encapsulation substrate to the display substrate thereby sealing the display unit therebetween; and etching the first inorganic base substrate and the third inorganic base substrate in a same process to reduce a thickness of the first inorganic base substrate and remove the third inorganic base substrate thereby exposing the second inorganic base substrate. Optionally, the second inorganic base substrate is made of a moisture-resistant and oxygen-resistant inorganic material having an etching rate smaller than that of the third inorganic base substrate for an etchant for etching the third inorganic base substrate.

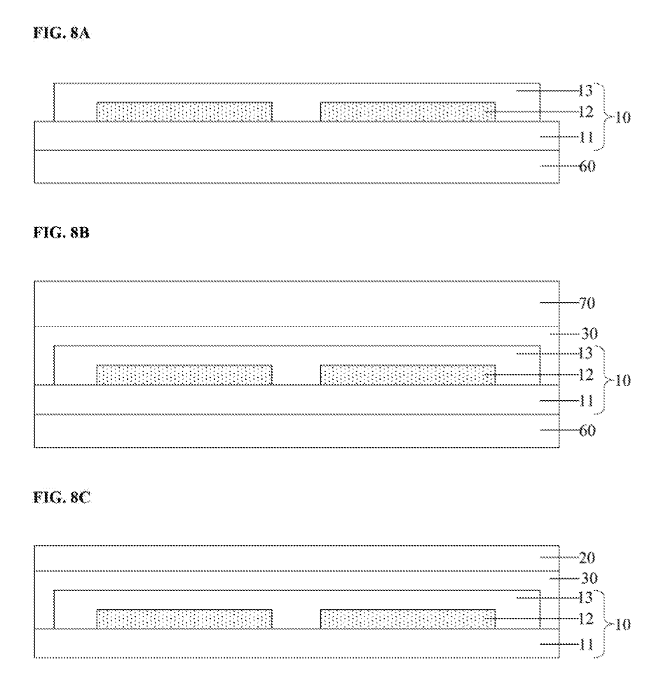

FIGS. 8A-8C shows a process of fabricating a flexible display panel in some embodiments according to the present disclosure. Referring to FIG. 8A, the method includes forming a second inorganic base substrate 11 on a carrier substrate 60, forming a display unit 12 on a side of the second inorganic base substrate 11 distal to the carrier substrate 60; and forming an encapsulating layer 13 to encapsulate the display unit 12, the encapsulating layer 13 being formed on a side of the display unit 12 distal to the second inorganic base substrate 11.

The second inorganic base substrate 11 is formed using a moisture-resistant and oxygen-resistant inorganic material having an etching rate smaller than that of the carrier substrate 60 for an etchant for etching the carrier substrate. Various appropriate materials and various appropriate fabricating methods may be used to make the second inorganic base substrate. For example, an inorganic base substrate material may be deposited by sputtering or a plasma-enhanced chemical vapor deposition (PECVD) process. Examples of appropriate materials for making the second inorganic base substrate include, but are not limited to, a silicon-containing inorganic material and a metal material. Examples of silicon-containing inorganic materials include silicon nitride (SiNₓ), amorphous silicon, and polycrystalline silicon. Examples of metal materials include gold, platinum, copper, molybdenum, and nickel. As compared to the polymer base substrate in the conventional flexible display panel, the second inorganic base substrate 11 in the present flexible display panel may be made substantially free of fabrication defects such as bubble and orifice. The flexible display panel may be made highly resistant to external moisture and oxygen.

Optionally, the second inorganic base substrate 11 is formed to have a single-layer structure. Optionally, the second inorganic base substrate 11 is formed to have a stacked-layer structure including two or more sub-layers. Optionally, the stacked-layer structure includes a metal sub-layer and a sub-layer made of a silicon-containing inorganic material.

In some embodiments, fabrication of the flexible display panel includes forming the second inorganic base substrate 11 on the carrier substrate 60, and assembling the encapsulation substrate to the display substrate together, and etching the first inorganic base substrate and the carrier substrate 60 in a same process, during which the carrier substrate 60 is removed. Accordingly, for making the second inorganic base substrate 11, an inorganic material having an etching rate smaller than that of the carrier substrate 60 for an etchant for etching the carrier substrate is selected. For example, an inorganic material having an etching rate no more than 0.2 μm/minute may be selected for making the second inorganic base substrate.

In some embodiments, the carrier substrate 60 is a glass substrate. Various appropriate etchants may be used for etching the glass substrate, including hydrofluoric acid, nitric acid, or a combination thereof, and optionally with one or more additives. Optionally, the second inorganic base substrate 11 has an etching rate smaller than that of the carrier substrate 60 for an etchant including hydrofluoric acid. Optionally, the second inorganic base substrate has an etching rate of no more than 0.2 μm/minute for an etchant including hydrofluoric acid.

In some embodiments, the second inorganic base substrate 11 is made of a metal material (e.g., insert metals) having an etching rate smaller than that of the carrier substrate 60 for an etchant for etching the carrier substrate 60.

In some embodiments, the step of forming the second inorganic base substrate 11 includes forming a sub-layer substantially resistant to the etchant for etching the glass substrate. For example, when the second inorganic base substrate 11 is made of a metal material or includes a metal sub-layer, the step of forming the second inorganic base substrate 11 may include forming a passivating protective sub-layer (e.g., an oxide protective film) on a surface proximal to the carrier substrate 60.

The encapsulating layer 13 may be made of any appropriate material (e.g., an inorganic material) and have various appropriate thickness, sufficient for providing requisite moisture resistance and oxygen resistance in the flexible display panel (e.g., in combination with the first inorganic base substrate).

Referring to FIG. 8B, the method in some embodiments further includes adhering an encapsulation substrate having an initial inorganic base substrate 70 to the display substrate 10 thereby sealing the display unit therebetween. The carrier substrate 60 has a thickness smaller than that of the initial inorganic base substrate 70. As shown in FIG. 8B, the encapsulation substrate and the display substrate 10 may be adhered together using an optical clean resin layer 30.

Optionally, the difference between the thicknesses of the carrier substrate 60 and the initial inorganic base substrate 70 is substantially the same as the thickness of the first inorganic base substrate in the final product.

Optionally, the difference between the thicknesses of the carrier substrate 60 and the initial inorganic base substrate 70 is larger than the thickness of the first inorganic base substrate in the final product. When the carrier substrate 60 and the initial inorganic base substrate 70 is etched in the subsequent etching step, an over-etching may be performed to ensure that carrier substrate 60 is completely removed. Because the second inorganic base substrate 11 has an etching rate smaller than that of the carrier substrate 60 (e.g., resistant to the etchant), the second inorganic base substrate 11 is substantially unaffected by the etchant whereas the etchant continues to etch the initial inorganic base substrate 70 until a desired thickness is achieved.

Referring to FIG. 8C, the method in some embodiments further includes etching the initial inorganic base substrate 70 and the carrier substrate 60 in a same process to reduce a thickness of the initial inorganic base substrate 70 and remove the carrier substrate 60 thereby exposing the second inorganic base substrate 11. For example, the etching process may be performed by soaking the adhered and sealed encapsulation substrate and display substrate in an etchant solution to etch the initial inorganic base substrate 70 and the carrier substrate 60 in a same process. In another example, the etching process may be performed by spraying an etchant solution to both sides of the adhered and sealed encapsulation substrate and display substrate, thereby etching, the initial inorganic base substrate 70 and the car substrate 60 in a same process.

Because the initial inorganic base substrate 70 has a thickness larger than that of the carrier substrate 60, when the carrier substrate 60 is completely removed by the etchant, the initial inorganic base substrate 70 is not. The remaining initial inorganic base substrate 70 becomes the first inorganic base substrate, which may be an ultrathin base substrate. Because the ultrathin base substrate is formed only after substantially all fabricating processes are complete, the present method is less prone to physical damages.

In some embodiments, the method farther includes, strengthening the first inorganic base substrate subsequent to the etching step, thereby forming a strengthened first inorganic base substrate in the encapsulation substrate. The strengthened first inorganic base substrate a high hardness and scratch resistance, obviating the need of having an additional cover glass, resulting in an ultrathin flexible display panel having a simplified structure. Optionally, the strengthened first inorganic base substrate has a Moh's hardness in a range of approximately 8 to approximately 9.

A flexible display panel fabricated by the present method has several advantages over the conventional flexible display panels. First, the base substrate of the display panel is made of an inorganic material, and is fabricated by directly depositing an inorganic material on a carrier substrate. The second base substrate in the present flexible display panel has excellent surface planarity, surface smoothness, mechanical stability, and structural integrity. Second, the base substrates in the flexible display panel fabricated by the present method are made of inorganic materials having a high hermeticity, obviating the fabrication defects in the conventional flexible display panel having a polymer base substrate. Third, the display unit in the present flexible display panel is encapsulated multiple times, e.g., by the encapsulating layer and the first inorganic base substrate having a high hermeticity, resulting in a flexible display panel highly resistant to moisture and oxygen. Fourth, the base substrates are made of inorganic material such as a strengthened glass material having a high hardness and scratch resistance, obviating the need of having an additional cover glass, resulting in an ultrathin flexible display panel having a simplified structure.

Optionally, the encapsulating, layer is formed to have a thickness in the range of approximately 0.01 μm to approximately 10 μm, e.g., approximately 0.01 μm to approximately 1.0 μm approximately 1.0 μm to approximately 1.5 μm, approximately 1.5 μm to approximately 2.0 μm, approximately 2.0 μm to approximately 5.0 μm, approximately 5.0 μm to approximately 10 μm.

Optionally, the encapsulating layer is formed using a plasma-enhanced chemical vapor deposition process. Optionally, an encapsulating layer having a thickness in a micrometer scale is fabricated by a plasma-enhanced chemical vapor deposition process. Optionally, the encapsulating layer is formed by atomic laser deposition. Optionally, an encapsulating layer having a thickness in a ten-nanometer scale is fabricated by atomic laser deposition.

In a flexible display panel fabricated by the present method, the display unit is encapsulated multiple times, e.g., by the encapsulating layer and the first inorganic base substrate having a high hermeticity, completely eliminating any permeation pathway for external moisture and oxygen. As a result, it is not requisite to have an encapsulating layer having multiple organic and inorganic sub-layers. A simplified and cost-effective fabrication process is made possible.

Optionally, the encapsulating layer is made of an inorganic material having a high hermeticity. Examples of appropriate inorganic materials for making the encapsulating layer include, but are not limited to, silicon nitride (SiNₓ) and silicon oxynitride (SiNₓO_{y}). Silicon nitride materials are highly hydrophobic and highly hermetic. Silicon oxynitride materials have excellent bonding with other layers of the flexible display panel. Moreover, an encapsulating layer made of one or more of these material have excellent surface planarity. A flexible display panel haying an encapsulating layer made of one or more of these materials is highly resistant to external moisture and oxygen.

Optionally, the initial inorganic base substrate has a thickness in a range of approximately 0.2 mm to approximately 1.0 mm, and a difference between the thickness of the third inorganic carrier substrate and that of the initial inorganic base substrate is no more than 0.1 mm, e.g., in a range of approximately 0.05 mm to approximately 0.1 mm.

Optionally, the first inorganic base substrate is formed to have a thickness no more than approximately 0.1 mm, e.g., in a range of approximately 0.05 mm to approximately 0.1 mm. By having this design, the flexible display panel may be made ultrathin, foldable, and rollable.

In some embodiments, prior to the step of adhering the encapsulation substrate to the display substrate, the method further includes forming a touch sensor in the encapsulation substrate. Optionally, the method further includes adhering the encapsulation substrate to the display substrate thereby sealing the display unit therebetween, the touch sensor after the adhering step is on a side of the initial inorganic base substrate proximal to the encapsulating layer in the display substrate.

Optionally, the touch sensor is a self-capacitive touch sensor having a touch electrode layer. Optionally, the touch sensor is a mutual capacitive touch sensor having a touch sensing electrode layer and a touch scanning electrode layer.

Various appropriate electrode materials and various appropriate fabricating methods may be used for making the touch sensor. For example, the electrode materials may be deposited by a plasma-enhanced chemical vapor deposition (PECVD) process or fabricated by a nanoimprinting lithography process. Examples of appropriate electrode materials for making the touch sensor include, but are not limited to, indium tin oxide, nano-silver, metal mesh, graphene, and carbon nanotubes.

In a flexible display panel fabricated by the present method, the touch sensor is formed on a side of the initial inorganic base substrate proximal to the encapsulating layer, thereby integrating the touch control function in the display module. This present method obviates the need of adhering an add-on touch panel to the display module, significantly reducing the overall thickness of the flexible display panel. The resulting flexible display panel may be made thinner and more flexible. By integrating touch sensor inside the display module, the subsequent base substrate etching can be conveniently performed.

In some embodiments, prior to the step of adhering the encapsulation substrate to the display substrate, the method further includes forming a color filter in the encapsulation substrate. Optionally, the method further includes adhering the encapsulation substrate to the display substrate thereby sealing the display unit therebetween, the color filter after the adhering step is on a side of the initial inorganic base substrate proximal to the encapsulating layer in the display substrate.

In some embodiments, the flexible display panel is formed to include a plurality of pixels, each of which including a subpixel of a first color, a subpixel of a second color, and a subpixel of a third color. Optionally, the step of forming the color filter includes forming a first color filter layer corresponding to the subpixel of the first color, forming a second color filter layer corresponding to the subpixel of the second color, and forming a third color filter layer corresponding to the subpixel of the third color. Optionally, the first color, the second color, and the third color are three different colors selected from red, green, and blue. Optionally, the subpixel of a first color, the subpixel of a second color, and the subpixel of a third color are three subpixels selected from a red subpixel, a green subpixel, and a blue subpixel. Optionally, the first color filter layer, the second color filter layer, and the third color filter layer are three color filter layers selected from a red color filter layer, a green color filter layer, and a blue color filter layer.

By having a color filter in the flexible display panel, e.g., on a side of the first inorganic base substrate proximal to the encapsulating layer, ambient light reflected by thin film transistor and display unit may be reduced or eliminated, enhancing display contrast. The color filter may be made to have a thickness much smaller than a polarizer in a conventional display panel. For example, the color filter in some embodiments may be made by a resin material having a thickness in a range of approximately 2 μm to approximately 6 μm. As compared to a flexible display panel fabricated by a conventional method, the flexible display panel fabricated by the present method may be made thinner and more flexible.

In some embodiments, prior to the step of adhering the encapsulation substrate to the display substrate, the method further includes forming a black matrix layer, e.g., in the encapsulation substrate. Optionally, the method further includes adhering the encapsulation substrate to the display substrate thereby sealing the display unit therebetween, the black matrix layer after the adhering step is on a side of the initial inorganic base substrate proximal to the encapsulating layer in the display substrate. The black matrix layer is formed in an inter-subpixel region of the flexible display panel, preventing color mixing among adjacent subpixels.

In some embodiments, the step of forming the encapsulation substrate includes forming a touch sensor on a first inorganic base substrate, and forming a color filter on a side of the touch sensor distal to the first inorganic base substrate and proximal to the encapsulating layer in the display substrate. The step of forming the color filter may include forming a first color filter layer, forming a second color filter layer, and forming a third color filter layer. By having this design, the touch sensor is directly disposed on the first inorganic base substrate. Because the first inorganic base substrate is substantially planar, the touch sensor can be made substantially planar, preventing occurrence of manufacturing defects. Optionally, the touch sensor in some embodiments is formed using one or more materials selected from graphene and carbon nanotubes.

In some embodiments, the step of forming the encapsulation substrate includes forming a color filter on a first inorganic base substrate, and forming a touch sensor on a side of the color filter distal to the first inorganic base substrate and proximal to the encapsulating layer in the display substrate. The step of forming color filter may include forming a first color filter layer, forming a second color filter layer, and forming a third color filter layer. By having this design, the color filter not only eliminates light reflected by the display unit and the thin film transistor, but also light reflected by the touch sensor, further enhancing display quality. Optionally, the touch sensor in some embodiments is formed using one or more materials selected from indium tin oxide, nano-silver, metal mesh, graphene, and carbon nanotubes.

In another aspect, the present disclosure provides a flexible display apparatus having a flexible display panel described herein or fabricated by a method described herein. Examples of appropriate display apparatuses includes, but are not limited to, an electronic paper, a mobile phone, a tablet computer, a television, a monitor, a notebook. computer, a digital album, a GPS, etc.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations ma be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A flexible display panel comprising a display substrate and an encapsulation substrate facing the display substrate;
wherein the encapsulation substrate comprises a first base substrate;
the display substrate comprises a second base substrate; a display unit on the second base substrate; and an encapsulating layer on a side of the display unit distal to the second base substrate and proximal to the encapsulation substrate; and
the second base substrate comprises a moisture-resistant and oxygen-resistant inorganic material having an etching rate smaller than that of a glass substrate for an etchant for etching the glass substrate.

2. The flexible display panel of claim 1, wherein the encapsulating layer comprises an inorganic material having a high hermeticity and has a thickness in a range of approximately 0.01 μm to approximately 10 μm.

3. The flexible display panel of claim 1, wherein the first base substrate has a thickness no more than approximately 0.1 mm.

4. The flexible display panel of claim 1, wherein the second base substrate has an etching rate smaller than that of the first base substrate for an etchant for etching the first base substrate.

5. The flexible display panel of claim 1, wherein the first base substrate is a strengthened glass substrate.

6. The flexible display panel of claim 1, further comprising a touch sensor on a side of the first base substrate proximal to the encapsulating layer.

7. The flexible display panel of claim 1, wherein the second base substrate comprises one or more of a silicon-containing inorganic material and a metal material.

8. The flexible display panel of claim 7, wherein the second base substrate comprises one or more of silicon nitride (SiNₓ), amorphous silicon, polycrystalline silicon, gold, platinum, copper, molydenum, and nickel.

9. The flexible display panel of claim 1, wherein the second base substrate comprises a sub-layer on a surface distal to the encapsulation substrate, the sub-layer being substantially resistant to the etchant for etching the glass substrate.

10. The flexible display panel of claim 1, wherein the encapsulating layer comprises one or more of silicon nitride (SiNₓ) and silicon oxynitride (SiNₓO_{y}).

11. The flexible display panel of claim 1, wherein the flexible display panel o a flexible organic light emitting diode display panel, and the display unit comprises an organic light emitting diode.

12. A flexible display apparatus, comprising a flexible display panel of claim 1,

13. A method of fabricating a flexible display panel, comprising:
forming a encapsulation substrate comprising a first base substrate;
forming a display substrate facing the encapsulation substrate on a third base substrate, the third base substrate having a thickness smaller than that of the first base substrate;
adhering the display substrate to the encapsulation substrate; and
etching the first base substrate and the third base substrate in a same process to reduce a thickness of the first base substrate and remove the third base substrate thereby exposing the display substrate.

14. The method of claim 3, wherein the step of forming the display substrate comprises:
forming a second base substrate on the third base substrate;
forming a display unit on a side of the second base substrate distal to the third base substrate; and
forming an encapsulating layer to encapsulate the display unit, the encapsulating layer being formed on a side of the display unit distal to the second base substrate and proximal to the encapsulation substrate;
the method further comprising:
adhering the encapsulation substrate to the display substrate thereby sealing the display unit therebetween; and
etching the first base substrate and the third base substrate in a same process to reduce a thickness of the first base substrate and remove the third base substrate thereby exposing the second base substrate;
wherein the second base substrate comprises a moisture-resistant, and oxygen-resistant inorganic material having an etching rate smaller than that of the third base substrate for an etchant for etching the third base substrate.

15. The method of claim 13, further comprising strengthening the first base substrate subsequent to etching the first base substrate and the third base substrate in the same process; thereby forming a strengthened first base substrate.

16. The method of claim 13, wherein, prior to etching the first base substrate and the third base substrate in a same process,
the first base substrate has a thickness in a range of approximately 0.2 mm to approximately 1.0 mm, and
a difference between the thickness of the third base substrate and that of the first base substrate is no more than 0.1 mm.

17. The method of claim 13, wherein a thickness of the first base substrate is reduced to a thickness of no more than approximately 0.1 mm subsequent to etching the first base substrate and the third base substrate in the same process.

18. The method of claim 14, wherein forming the second base substrate comprises forming a sub-layer on a surface proximal to the third base substrate, the sub-layer being substantially resistant to the etchant for etching the glass substrate.

19. The method of claim 14, wherein the encapsulating layer is formed using an inorganic material having a high hermeticity, and is formed to have a thickness in a range of approximately 0.01 mm to approximately 10 μm.

20. A flexible display panel fabricated by a method of claim 13.
